(19) United States
(12) Patent Application Publication
(10) Pub. No.: US 2007/0183229 A1
(43) Pub. Date: Aug. 9, 2007

(54) Multi chip package and related method

(76) Inventors: Seouk-Kyu Choi, Hwaseong-si (KR); Woo-Pyo Jeong, Seoul (KR)

Correspondence Address: VOLENTINE & WHITT PLLC, ONE FREEDOM SQUARE, 11951 FREEDOM DRIVE SUITE 1260, RESTON, VA, 20190, US

(21) Appl. No.: 11/655,161

(22) Filed: Jan. 19, 2007

(30) Foreign Application Priority Data
Feb. 9, 2006 (KR) 2006-12733

(51) Int. Cl. G11C 29/00

(52) U.S. Cl. 365/200

(57) ABSTRACT

A Multi Chip Package (MCP) and a related method for enabling a cell in the MCP are provided. In one embodiment, the MCP comprises a first memory device and a second memory device storing repair address information about the first memory device.

### BACKGROUND

1. Field of the Invention

Embodiments of the invention relate to a semiconductor memory device and a related method. In particular, embodiments of the invention relate to a Multi Chip Package (MCP) and a method for enabling a cell in the MCP.

This application claims priority to Korean Patent Application No. 2006-12733, filed on Feb. 9, 2006, the subject matter of which is hereby incorporated by reference in its entirety.

2. Description of Related Art

Multi Chip Package (MCP) technology allows multiple chips to be mounted in a single package. An MCP includes a plurality of semiconductor memories in a single chip. Examples of the types of semiconductor memories that may be disposed in an MCP are NAND flash memory, NOR flash memory, dynamic random access memory (DRAM), and static random access memory (SRAM). The market for MCP technology is growing rapidly, and the growing market for relatively small electronic devices such as mobile phones is contributing to the growth of the MCP market. MCPs are widely used in various mobile devices and the demand for MCPs is rapidly increasing. It is expected that MCPs will be adopted in all mobile phones, and MCP technology is currently used in 100% of Japanese mobile phones. In addition, MCP technology is considered to be the next generation solution in semiconductor device technology.

The reason for the rapid growth of the MCP technology market is that, as the sizes of portable devices such as mobile phones and Personal Digital Assistants (PDAs) are reduced, the demand for MCPs that occupy a relatively small area increases. In recent years, as various functions such as digital camera and MP3 playback functions have been added to portable devices, the demand for MCPs has been greatly increasing.

Figure (FIG.) 1 is a block diagram of a conventional MCP. Referring to FIG. 1, a conventional MCP 100 includes a central processing unit (CPU) 120, a DRAM device 140, a read only memory (ROM) device 160, and a flash memory device 180. DRAM device 140 is a volatile memory device, while ROM device 160 and flash memory device 180 are each nonvolatile memory devices. In accordance with a method for enabling a cell of a conventional volatile memory device (i.e., a redundancy method for the conventional volatile memory device), when a repair address is input, a redundancy cell is enabled using a fuse. However, the fuse makes it difficult to increase the degree of integration of the volatile memory device. Furthermore, that difficulty influences the increase in the integration density of conventional MCP 100, which includes a plurality of memories including the volatile memory device and may make it difficult to increase the integration density of conventional MCP 100.

### SUMMARY

Embodiments of the invention provide an MCP having a memory device adapted to perform a method for enabling a cell without using any fuses, and provide the method for enabling a cell without using any fuses.

In one embodiment, the invention provides a multi chip package comprising a first memory device and a second memory device storing repair address information about the first memory device.

In another embodiment, the invention provides a method for enabling a cell in a multi chip package comprising a first memory device and a second memory device storing repair address information about the first memory device. The method comprises determining whether a first address is a repair address, wherein the first address is an address of a normal cell disposed in the first memory device; reading the repair address information from the second memory device when the first address is a repair address; and enabling a redundancy cell in the first memory device in accordance with the repair address information when the first address is a repair address.

### BRIEF DESCRIPTION OF THE DRAWINGS

Embodiments of the invention will be described herein with reference to the accompanying drawings. In the drawings:

FIG. 1 is a block diagram of a conventional Multi Chip Package (MCP);

FIG. 2 is a block diagram of an MCP in accordance with an embodiment of the invention; and,

FIG. 3 is a flowchart illustrating a method for enabling a cell disposed in an MCP in accordance with an embodiment of the invention.

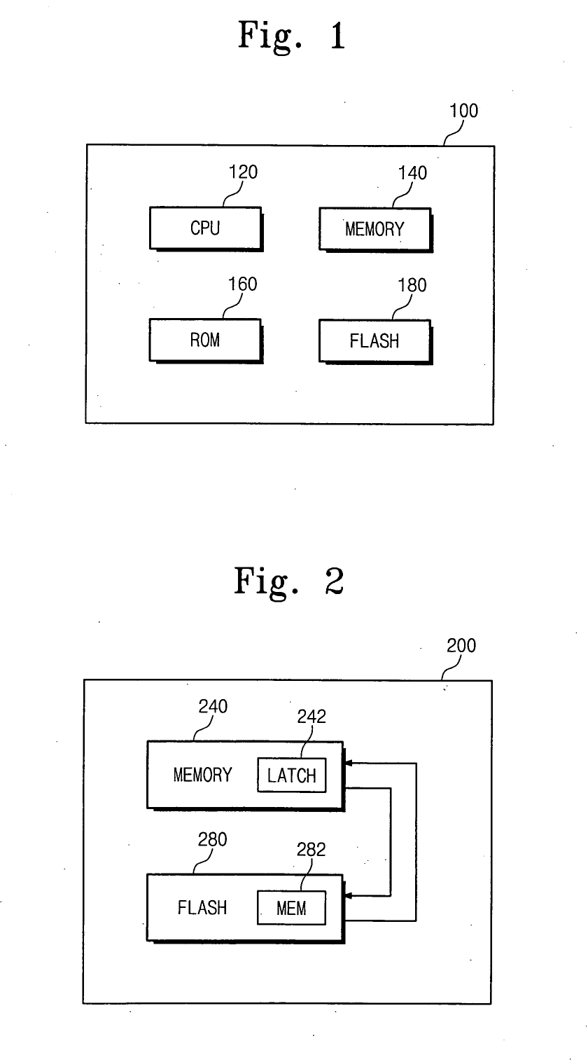

### DESCRIPTION OF EMBODIMENTS

FIG. 2 is a block diagram of a Multi Chip Package (MCP) 200 in accordance with an embodiment of the invention. Referring to FIG. 2, MCP 200 comprises a memory device 240 and a flash memory device 280.

Memory device 240 is a volatile memory device, such as a DRAM device or a synchronous DRAM (SDRAM) device. Memory device 240 comprises a latch 242. When one or more defective memory cells are detected in memory device 240 during a manufacturing process, repair address information about the defective memory cell(s) is stored in a nonvolatile memory device 282 of flash memory device 280. In particular, the address of each defective cell is stored as a repair address in the repair address information. Nonvolatile memory device 282 may be referred to hereinafter as MEM 282. In addition, the repair address information stored in MEM 282 comprises redundancy information for memory device 240. The redundancy information comprises a command for enabling a redundancy cell when a command for enabling a normal memory cell corresponding to a repair address is input. Thus, memory device 240 of MCP 200 can perform the redundancy operation without using any fuses. Memory cells that are not redundancy cells may be referred to herein as “normal” memory cells or “normal” cells.

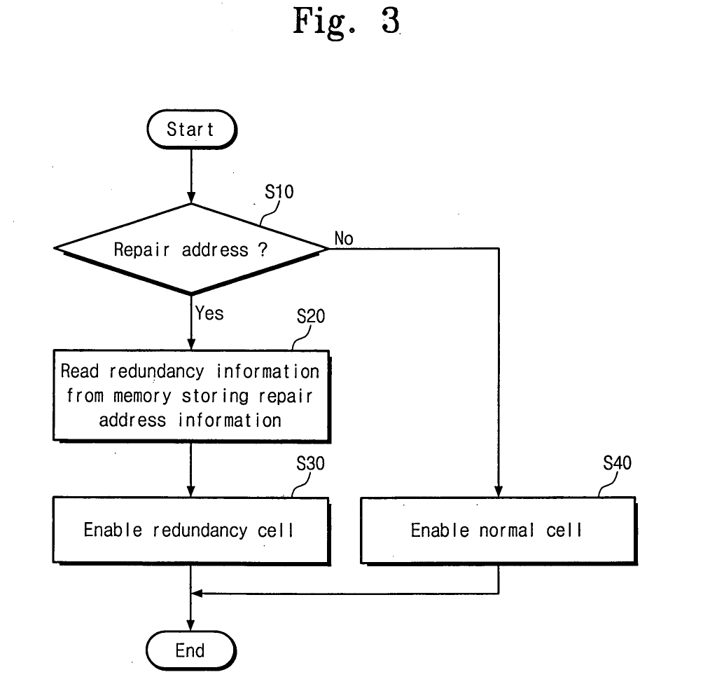

FIG. 3 is a flowchart illustrating a method for enabling a cell of MCP 200 (i.e., a redundancy method) in accordance with an embodiment of the invention.

Referring to FIG. 3, when a cell (i.e., a normal cell) in memory device 240 of MCP 200 is to be enabled, it is determined whether the address of that cell is a repair address (i.e., whether the address of that cell is included among the repair addresses) (S10). The repair address information has previously been stored in MEM 282 of flash memory device 280 during the manufacturing process.

When it is determined that the address of the cell is not a repair address, memory device 240 enables the cell (which is a normal cell) in accordance with the address of the cell (S40).

However, when the address of the cell is a repair address, memory device 240 reads the repair address information from MEM 282 of flash memory device 280 (S20). The repair address information comprises the corresponding redundancy information, and the redundancy information contains information for enabling a redundancy cell corresponding to the repair address. The information read from MEM 282 of flash memory device 280 is transferred to latch 242 of memory device 240.

The corresponding redundancy cell is then enabled in accordance with the redundancy information stored in latch 242 of memory device 240 (S30).

An operation of enabling a cell in memory device 240 of MCP 200 (i.e., a redundancy operation) is performed through the process described above. Thus, in accordance with an embodiment of the invention, the operation of enabling a cell in memory device 240 of MCP 200 uses no fuses. Therefore, MCP 200 and the related method of enabling a cell, in accordance with embodiments of the invention, are advantageous for increasing the degree of integration of both MCP 200 and memory device 240.

As described above, using the second memory device storing repair address information for the first memory device, a MCP can perform a method for enabling a cell disposed in the first memory device (i.e., a redundancy operation for the first memory device) without using any fuses.

Although embodiments of the invention have been described herein, modifications may be made to the embodiments by those skilled in the art without departing from the scope of the invention as defined by the accompanying claims.

What is claimed is:

1. A multi chip package comprising:
a first memory device; and,
a second memory device storing repair address information about the first memory device.

2. The multi chip package of claim 1, wherein the first memory device comprises a latch adapted to store the repair address information read from the second memory device.

3. The multi chip package of claim 1, wherein the first memory device is a volatile memory device.

4. The multi chip package of claim 1, wherein the second memory device is a nonvolatile memory device.

5. The multi chip package of claim 1, wherein the second memory is an electrically erasable programmable read only memory (EEPROM) device or a flash memory device.

6. A method for enabling a cell in a multi chip package comprising a first memory device and a second memory device storing repair address information about the first memory device, the method comprising:
determining whether a first address is a repair address, wherein the first address is an address of a normal cell disposed in the first memory device;
reading the repair address information from the second memory device when the first address is a repair address; and,
enabling a redundancy cell in the first memory device in accordance with the repair address information when the first address is a repair address.

7. The method of claim 6, further comprising:
enabling the normal cell when the first address is not a repair address.
